(19) United States
(12) Patent Application Publication
(10) Pub. No.: US 2010/0311245 A1
(43) Pub. Date: Dec. 9, 2010

(54) SUBSTRATE PROCESSING METHOD

(75) Inventor: Masanobu Honda, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/792,863

(22) Filed: Jun. 3, 2010

Related U.S. Application Data
(60) Provisional application No. 61/222,809, filed on Jul. 2, 2009.

(30) Foreign Application Priority Data
Jun. 5, 2009 (JP) 2009-136269

(51) Int. Cl. H01L 21/3065

(52) U.S. Cl. 438/710; 257/E21.218

(57) ABSTRACT

A substrate processing method performs a processing on a wafer W having an amorphous carbon film 51, a SiON film 52, a BARC film 53 and a photoresist film 54 formed on top of each other in sequence. In the substrate processing method, a shrinking-etching process and a non-uniformity-suppressing process are performed as a single process. The shrinking-etching process etches the SiON film 52 on bottom portions of openings 55 of the photoresist film 54 while reducing CD values of the openings 55 by plasma generated from a gaseous mixture of a CHF₃ gas, a CF₃I gas, a H₂ gas and a N₂ gas. The non-uniformity-suppressing process suppresses non-uniformity in the CD values by facilitating deposition of deposits on sidewall surfaces of the openings 55.

### CROSS-REFERENCE TO RELATED APPLICATION

This application claims the benefit of Japanese Patent Application No. 2009-136269 filed on Jun. 5, 2009, and U.S. Provisional Patent Application Ser. No. 61/222,809 filed on Jul. 2, 2009, the entire disclosures of which are incorporated herein by reference.

### FIELD OF THE INVENTION

The present disclosure relates to a substrate processing method, and, more particularly, to a substrate processing method for processing a substrate on which a processing target layer, an intermediate layer and a mask layer are formed in sequence.

### BACKGROUND OF THE INVENTION

For a semiconductor device, there is known a wafer having, on a silicon base, an impurity-containing oxide film such as a TEOS (Tetra Ethyl Ortho Silicate) film formed by a CVD process or the like; a conductive film such as a TiN film; an antireflection film (BARC film); and a photoresist film in sequence (see, for example, Patent Document 1). The photoresist film is formed to have a preset pattern by photolithography and is used as a mask during the etching of the antireflection film and the conductive film. Besides, also known are a wafer having a SiON film instead of the TiN film and a wafer having a Si-ARC film formed as an intermediate film between an etching target film and a photoresist film so as to be used as a hard mask and an antireflection film.

A circuit pattern is formed on a surface of such a wafer by, e.g., plasma etching. For example, Patent Document 2 discloses a conventional etching method for forming, e.g., a contact hole of a high aspect ratio.

Further, with the recent trend for miniaturization of semiconductor devices, there is a demand for forming a finer circuit pattern on a surface of such a wafer as described above. To form such a finer circuit pattern, a small-dimension opening (via hole or trench) needs to be formed on an etching target film by reducing a minimum pattern dimension on a photoresist film in a manufacturing process of a semiconductor device.

Patent Document 1: Japanese Patent Laid-open Publication No. 2006-190939

Patent Document 2: Japanese Patent Laid-open Publication No. 2002-016050

The minimum pattern dimension on the photoresist film is determined based on a minimum dimension that can be developed by photolithography. Due to non-uniformity in focal lengths, however, the minimum pattern dimension producible by the photolithography cannot be reduced below a certain limit. For example, the minimum pattern dimension producible by the photolithography is about 80 nm, whereas a required dimension satisfying the recent miniaturization of the semiconductor devices is about 30 nm.

In this regard, various substrate processing technologies have been proposed to achieve a smaller pattern dimension satisfying the requirement for the miniaturization of the semiconductor devices.

A conventional substrate processing method, however, may not be satisfactory in view of controllability. For example, there is no established substrate processing method capable of independently controlling suppression of non-uniformity in opening widths (CD (Critical Dimension) values) of a circuit pattern; and a reduction width indicating the degree of reduction of the CD values.

### BRIEF SUMMARY OF THE INVENTION

In view of the foregoing, the present disclosure provides a high-controllability substrate processing method capable of forming, in a mask layer or an intermediate layer, an opening having a dimension satisfying the requirement for miniaturization of a semiconductor device. For example, the present disclosure provides a substrate processing method capable of independently controlling suppression of non-uniformity in CD values and a reduction width of the CD values.

In accordance with one aspect of the present disclosure, there is provided a substrate processing method for processing a substrate having a processing target layer, an intermediate layer and a mask layer formed on top of each other in sequence and the mask layer has openings through which a part of the intermediate layer is exposed. The method includes a non-uniformity-suppressing/shrinking-etching process of performing a shrinking-etching process and a non-uniformity-suppressing process as a single process. Further, in the shrinking-etching process, the intermediate layer forming bottom portions of the openings is etched while widths of the openings are reduced by plasma generated from a gaseous mixture of a deposition gas, an anisotropic etching gas and a hydrogen (H₂) gas. Furthermore, in the non-uniformity-suppressing process, non-uniformity in widths of the openings is suppressed by facilitating deposition of deposits on sidewall surfaces of the openings of the mask layer.

Moreover, in the substrate processing method, in the non-uniformity-suppressing/shrinking-etching process, a feed amount of the hydrogen (H₂) gas may be controlled depending on the non-uniformity in the widths of the openings.

In the substrate processing method, the feed amount of the hydrogen (H₂) gas may be controlled such that a volume ratio of the feed amount of the hydrogen (H₂) gas to a feed amount of the anisotropic etching gas is within a range of about 25% to about 65%.

In the substrate processing method, in the non-uniformity-suppressing/shrinking-etching process, a deposition gas may be used instead of the hydrogen (H₂) gas.

In accordance with another aspect of the present disclosure, there is provided a substrate processing method for processing a substrate having a processing target layer, an intermediate layer and a mask layer formed on top of each other in sequence and the mask layer has openings through which a part of the intermediate layer is exposed. The method includes a non-uniformity-maintaining/shrinking-etching process of performing a shrinking-etching process and an opening-width-reducing process as a single process. Further, in the shrinking-etching process, the intermediate layer forming bottom portions of the openings is etched while widths of the openings are reduced by plasma generated from a gaseous mixture of a deposition gas, an anisotropic etching gas and a nitrogen (N₂) gas. Furthermore, in the opening-width-reducing process, widths of the openings are reduced while non-uniformity in the widths of the openings is maintained by forming a thin film on inner wall surfaces of the openings of the mask layer.

Moreover, in the substrate processing method, in the non-uniformity-maintaining/shrinking-etching process, a feed amount of the nitrogen (N₂) gas may be controlled depending on a reduction width of the opening.

In the substrate processing method, the feed amount of the nitrogen (N₂) gas may be controlled such that a volume ratio of the feed amount of the nitrogen (N₂) gas to a feed amount of the anisotropic etching gas is within a range of about 25% to about 125%.

In accordance with still another aspect of the present disclosure, there is provided a substrate processing method for processing a substrate having a processing target layer, an intermediate layer and a mask layer formed on top of each other in sequence and the mask layer has openings through which a part of the intermediate layer is exposed. The method includes a non-uniformity-suppressing/opening-width-reducing/shrinking-etching process of performing a shrinking-etching process, a non-uniformity-suppressing process and an opening-width-reducing process as a single process. Further, in the shrinking-etching process, the intermediate layer forming bottom portions of the openings is etched while widths of the openings are reduced by plasma generated from a gaseous mixture of a deposition gas, an anisotropic etching gas, a hydrogen (H₂) gas and a nitrogen (N₂) gas. Furthermore, in the non-uniformity-suppressing process, non-uniformity in the widths of the openings is suppressed by facilitating deposition of deposits on sidewall surfaces of the openings of the mask layer. Furthermore, in the opening-width-reducing process, the widths of the openings are reduced by forming a thin film on inner surfaces of the openings.

Moreover, in the substrate processing method, in the non-uniformity-suppressing/opening-width-reducing/shrinking-etching process, a feed amount of the hydrogen (H₂) gas may be controlled depending on the non-uniformity in the widths of the openings, and a feed amount of the nitrogen (N₂) gas may be controlled depending on a reduction width of the opening.

In the substrate processing method, the feed amounts of the hydrogen (H₂) gas and the nitrogen (N₂) gas may be controlled such that volume ratios of the feed amounts of the hydrogen (H₂) gas and the nitrogen (N₂) gas to a feed amount of the anisotropic etching gas may be within a range of about 25% to about 65% and within a range of about 25% to about 125%, respectively.

In the substrate processing method, in the non-uniformity-suppressing/opening-width-reducing/shrinking-etching process, a deposition gas may be used instead of the hydrogen (H₂) gas.

In the substrate processing method, the deposition gas may be represented by a general formula of CₓH_{y}F_{z} (x, y and Z are 0 or positive integers).

In the substrate processing method, the deposition gas may be a CHF₃ gas.

In the substrate processing method, the anisotropic etching gas may be a gas containing bromine (Br) or a halogen element having an atomic number greater than that of bromine (Br), or sulfur (S) or other elements having an atomic number greater than that of sulfur (S) in a group 16 on a periodic table.

In the substrate processing method, the anisotropic etching gas may be a CF₃I gas, a CF Br gas, a HI gas or a HBr gas.

In accordance with the above-mentioned substrate processing method, the shrinking-etching process and the non-uniformity-suppressing process are performed as a single process. In the shrinking-etching process, the intermediate layer forming bottom portions of the openings of the mask layer is etched while the widths of the openings are reduced by the plasma generated from the gaseous mixture of the deposition gas, the anisotropic etching gas and the hydrogen (H₂) gas. In the non-uniformity-suppressing process, the non-uniformity in the widths of the openings of the mask layer is suppressed by facilitating the deposition of the deposits on the sidewall surfaces of the openings of the mask layer. Therefore, in the shrinking-etching process, a CD non-uniformity-suppressing effect and an opening-width-reducing effect can be independently controlled.

Further, in the substrate processing method, the feed amount of the hydrogen (H₂) gas may be controlled depending on the non-uniformity in the widths of the openings. Therefore, even in case the substrate has openings of which widths are largely non-uniform, the non-uniformity in the widths of the openings can be effectively suppressed, and, thus, an unnecessary use of the processing gas can be avoided.

In the substrate processing method, the feed amount of the hydrogen (H₂) gas may be controlled such that the volume ratio of the feed amount of the hydrogen (H₂) gas to the feed amount of the anisotropic etching gas is within the range of about 25% to about 65%. Therefore, the non-uniformity in the widths of the openings can be effectively suppressed, depending on the degree of the non-uniformity in the widths of the openings.

In the substrate processing method, in the non-uniformity-suppressing/shrinking-etching process, the deposition gas may be used instead of the hydrogen (H₂) gas. Therefore, the number of the kinds of the used processing gases can be reduced, so that controllability in the substrate processing method may be improved.

Further, in accordance with the above-mentioned substrate processing method, the shrinking-etching process and the opening-width-reducing process are performed as a single process. In the shrinking-etching process, the intermediate layer forming bottom portions of the openings of the mask layer is etched while the widths of the openings are reduced by the plasma generated from the gaseous mixture of the deposition gas, the anisotropic etching gas and the nitrogen (N₂) gas. Furthermore, in the opening-width-reducing process, the widths of the openings of the mask layer are reduced while the non-uniformity in the widths of the openings is maintained by forming the thin film on the inner wall surfaces of the openings of the mask layer. Therefore, in the shrinking-etching process, an opening width non-uniformity-suppressing effect and an opening-width-reducing effect can be independently controlled.

Moreover, in the substrate processing method, the feed amount of the nitrogen (N₂) gas may be controlled depending on the reduction width of the opening. Therefore, a substrate having a desired CD reduced width can be easily obtained.

In the substrate processing method, the feed amount of the nitrogen (N₂) gas may be controlled such that the volume ratio of the feed amount of the nitrogen (N₂) gas to the feed amount of the anisotropic etching gas is within the range of about 25% to about 125%. Therefore, a substrate having a desired CD reduced width can be easily obtained.

Further, in accordance with the substrate processing method, the shrinking-etching process, the non-uniformity-suppressing process and the opening-width-reducing process are performed as a single process. In the shrinking-etching process, the intermediate layer forming bottom portions of the openings of the mask layer is etched while the widths of the openings are reduced by the plasma generated from the gaseous mixture of the deposition gas, the anisotropic etching gas, the hydrogen (H₂) gas and the nitrogen (N₂) gas. In the non-uniformity-suppressing process, the non-uniformity in the widths of the openings of the mask layer is suppressed by facilitating the deposition of the deposits on the sidewall surfaces of the openings of the mask layer.

In the opening-width-reducing process, the widths of the openings are reduced by forming the thin film on the inner surfaces of the openings. Therefore, in the shrinking-etching process, an opening-width non-uniformity-suppressing effect and an opening-width-reducing effect can be independently controlled.

In the substrate processing method, in the non-uniformity-suppressing/opening-width-reducing/shrinking-etching process, the feed amount of the hydrogen (H₂) gas may be controlled depending on the non-uniformity in the widths of the openings, and the feed amount of the nitrogen (N₂) gas may be controlled depending on the reduction width of the opening. Therefore, the non-uniformity in the widths of the openings can be suppressed depending on the degree of the non-uniformity in the widths of the openings, and the widths of the openings can be reduced to desired reduction widths.

In the substrate processing method, the feed amounts of the hydrogen (H₂) gas and the nitrogen (N₂) gas may be controlled such that volume ratios of the feed amounts of the hydrogen (H₂) gas and the nitrogen (N₂) gas to the feed amount of the anisotropic etching gas may be within the range of about 25% to about 65% and within the range of about 25% to about 125%, respectively. Therefore, the non-uniformity in the widths of the openings can be effectively suppressed depending on the degree of the non-uniformity in the widths of the openings, and a substrate having a desired CD reduced value can be easily obtained.

In the substrate processing method, the deposition gas may be used instead of the hydrogen (H₂) gas in the non-uniformity-suppressing/opening-width-reducing/shrinking-etching process. Therefore, the number of the kinds of the used processing gases can be reduced, so that controllability in the substrate processing method may be improved.

In the substrate processing method, the deposition gas may be represented by the general formula of CₓH_{y}F_{z} (x, y and Z are 0 or positive integers). Therefore, the deposits can be effectively deposited on the sidewall surfaces of the openings, so that the widths of the openings can be reduced.

In the substrate processing method, the deposition gas may be the CHF₃ gas. Therefore, the deposits can be effectively deposited on the sidewall surfaces of the openings, so that the widths of the openings can be reduced.

In the substrate processing method, the anisotropic etching gas may be the gas containing bromine (Br) or the halogen element having the atomic number greater than that of bromine (Br), or sulfur (S) or other elements having the atomic number greater than that of sulfur (S) in the group 16 on the periodic table. Therefore, the plasma generated from the anisotropic etching gas can be allowed to reach a bottom portion of the opening, so that the processing target layer can be etched while deposition of the deposits on the bottom portion of the opening is suppressed.

In the substrate processing method, the anisotropic etching gas may be the CF₃I gas, the CF₃Br gas, the HI gas or the HBr gas. Therefore, an effect of suppressing the deposition of the deposit on the bottom portion of the opening and an effect of etching the bottom portion of the opening can be improved.

### BRIEF DESCRIPTION OF THE DRAWINGS

The disclosure may best be understood by reference to the following description taken in conjunction with the following figures:

FIG. 1 is a plane view schematically illustrating a configuration of a substrate processing system performing a substrate processing method in accordance with an embodiment of the present disclosure;

FIG. 2 is a cross sectional view taken along a line II-II of FIG. 1;

FIG. 3 is a cross sectional view schematically illustrating a structure of a semiconductor wafer on which a plasma process is performed in the substrate processing system of FIG. 1;

FIGS. 4A to 4E are process diagrams illustrating the substrate processing method in accordance with the embodiment of the present disclosure;

FIG. 5 is a chart showing results of experimental examples and a comparative example; and

FIG. 6 is a chart showing results of experimental examples and the comparative example.

### DETAILED DESCRIPTION OF THE INVENTION

Hereinafter, embodiments of the present disclosure will be described with reference to the accompanying drawings.

First, a substrate processing system performing a substrate processing method in accordance with an embodiment of the present disclosure will be described. The substrate processing system includes a plurality of process modules configured to perform an etching process or an asking process on a semiconductor wafer W (hereinafter, simply referred to as a “wafer W”) as a substrate by plasma.

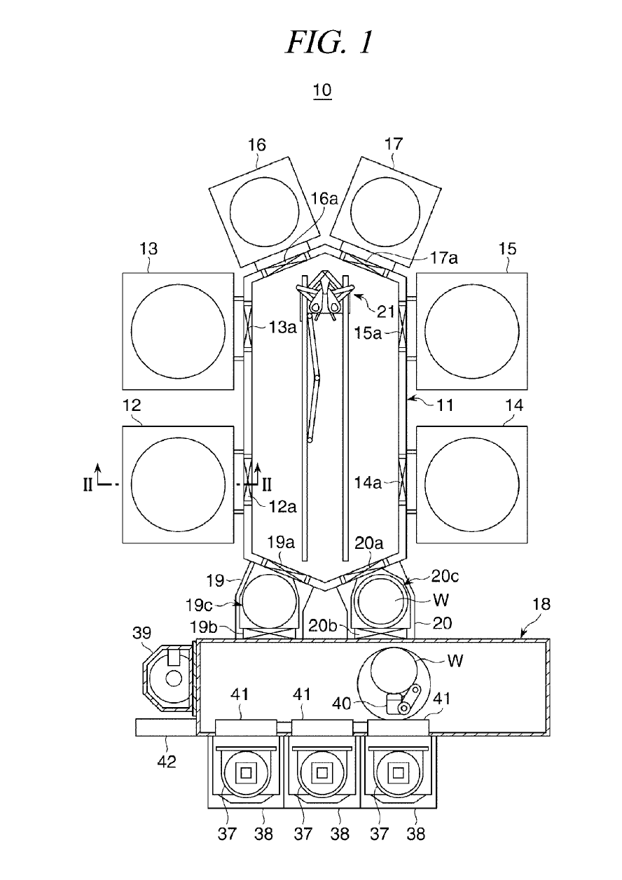

FIG. 1 is a plane view schematically illustrating the substrate processing system performing the substrate processing method in accordance with the embodiment of the present disclosure.

In FIG. 1, the substrate processing system 10 includes a transfer module 11 having a hexagonal shape when viewed from the top thereof; two process modules 12 and 13 connected to one side of the transfer module 11; two process modules 14 and 15 connected to the opposite side of the transfer module 11 from the two process modules 12 and 13; a process module 16 adjacent to the process module 13 and connected to the transfer module 11; a process module 17 adjacent to the process module 15 and connected to the transfer module 11; a rectangular loader module 18 serving as a transfer chamber; and two load lock modules 19 and 20 provided between the transfer module 11 and the loader module 18 while connecting the transfer module 11 and the loader module 18.

The transfer module 11 includes therein a transfer arm 21 capable of making contracting, extending and revolving motions. Further, the transfer arm 21 transfers the wafer W between the process modules 12 to 17 and the load lock modules 19 and 20.

The process module 12 includes a processing vessel (chamber) accommodating the wafer W therein. A gaseous mixture of, e.g., a CHF₃ gas and a HBr gas as a processing gas is introduced into the chamber and an electric field is generated within the chamber, so that plasma is excited from the introduced processing gas. Therefore, an etching process is performed on the wafer W by the plasma.

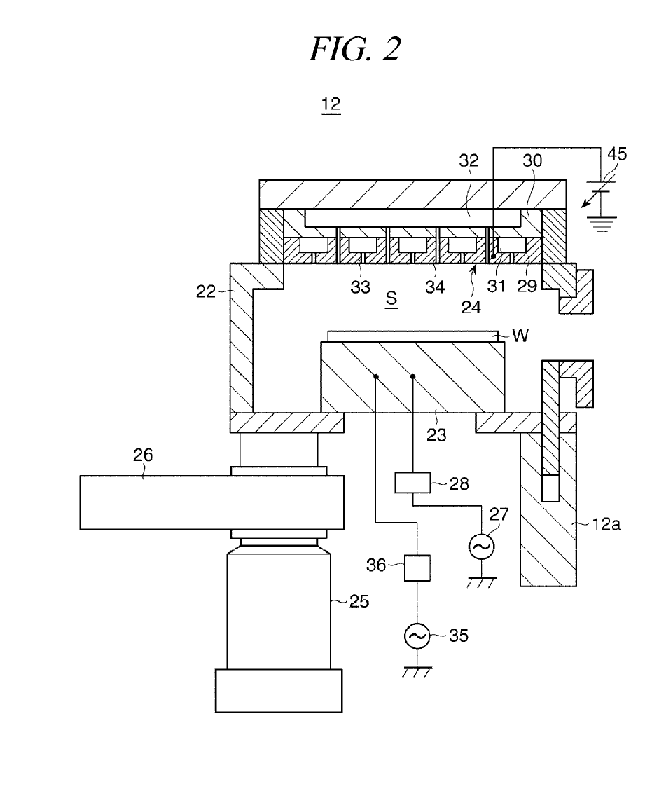

FIG. 2 is a cross sectional view taken along a line II-II of FIG. 1.

In FIG. 2, the process module 12 includes a processing chamber 22; a mounting table 23 provided within the chamber 22 so as to mount thereon the wafer W; a shower head 24 provided in an upper portion of the chamber 22 so as to face the mounting table 23; a TMP (Turbo Molecular Pump) 25 configured to exhaust a gas or the like from the chamber 22; and an APC (Adaptive Pressure Control) valve 26 provided between the chamber 22 and the TMP 25 so as to serve as a variable butterfly valve for controlling an internal pressure of the chamber 22.

A first high frequency power supply 27 and a second high frequency power supply 35 are coupled to the mounting table 23 via a first matcher 28 and a second matcher 36, respectively. The first high frequency power supply 27 applies a high frequency power of a relatively high frequency of, e.g., about 60 MHz, to the mounting table 23 as an excitation power. Meanwhile, the second high frequency power supply 35 applies a high frequency power of a relatively low frequency of, e.g., about 2 MHz, to the mounting table 23 as a bias power. Accordingly, the mounting table 23 serves as a lower electrode applying a high frequency power into a processing space S between the mounting table 23 and the shower head 24. The matchers 28 and 36 are configured to reduce reflection of the high frequency powers from the mounting table 23, thus maximizing a supply efficiency of the high frequency powers to the mounting table 23.

The shower head 24 includes a lower layer gas feed member 29 of a circular plate shape and an upper layer gas feed member 30 of a circular plate shape. The upper layer gas feed member 30 is placed on top of the lower layer gas feed member 29. The lower layer gas feed member 29 has a first buffer room 31, and the upper layer gas feed member 30 has a second buffer room 32. The first buffer room 31 and the second buffer room 32 communicate with the inside of the chamber 22 through gas ventilation holes 33 and 34, respectively.

The first buffer room 31 is coupled to, e.g., a CHF₃ gas feed system (not shown). The CHF₃ gas feed system feeds the CHF₃ gas into the first buffer room 31. The CHF₃ gas is then supplied into the chamber 22 through the gas ventilation holes 33. Further, the second buffer room 32 is coupled to, e.g., a HBr gas feed system (not shown). The HBr gas feed system feeds the HBr gas into the second buffer room 32. The HBr gas is then supplied into the chamber 22 through the gas ventilation holes 34.

A DC power supply 45 is connected to the shower head 24, and a DC voltage is applied to the shower head 24 from the DC power supply 45. Therefore, the applied DC voltage is used to control an ion distribution within the processing space S.

In the chamber 22 of the processing module 12 configured as described above, by applying the high frequency power to the processing space S from the mounting table 23 as described above, the processing gas supplied into the processing space S from the shower head 24 is excited into high-density plasma, so that ions and/or radicals are generated. By the ions and/or the radicals, an etching process is performed on the wafer W.

Referring back to FIG. 1, the process module 13 includes a processing chamber configured to accommodate therein the wafer W on which the etching process has been already performed in the process module 12. A gaseous mixture of an O₂ gas and a N₂ gas as a processing gas is introduced into this chamber and an electric field is generated within the chamber, so that plasma is excited from the introduced processing gas. Accordingly, an etching process is performed on the wafer W by this plasma. Further, the process module 13 has substantially same configuration as that of the process module 12, and it may include an O₂ gas feed system and a N₂ gas feed system (both are not shown) instead of the CHF₃ gas feed system and the HBr gas feed system. Furthermore, the etching process in the process module 13 may be performed with an asking process.

The process module 14 includes a processing chamber configured to accommodate therein the wafer W on which the etching process has been already performed in the process module 13. An O₂ gas as a processing gas is introduced into this chamber, and an electric field is generated within the chamber, so that plasma is excited from the introduced processing gas. Accordingly, an asking process is performed on the wafer W by this plasma. The process module 14 has substantially same configuration as that of the process module 12, and, instead of the shower head 24 having the lower layer gas feed member 29 and the upper layer gas feed member 30, the process module 14 has a shower head including a single circular plate-shaped gas feed member whose buffer room is coupled to an O₂ gas feed system (all of them are not shown).

The inside of the transfer module 11 and the inside of the process modules 12 to 17 are maintained in depressurized states, and the transfer module 11 and the process modules 12 to 17 are connected via vacuum gate valves 12a to 17a, respectively.

In the substrate processing system 10, an internal pressure of the loader module 18 is maintained at an atmospheric pressure, whereas an internal pressure of the transfer module 11 is maintained at a vacuum. Accordingly, the load lock modules 19 and 20 have vacuum gate valves 19a and 20a at their joint portions with the transfer module 11, respectively, while the load lock modules 19 and 20 have atmospheric door valves 19b and 20b at their joint portions with the loader module 18, respectively. With this configuration, each load lock module is configured as a preliminary transfer chamber whose internal pressure is adjustable. Further, the load lock modules 19 and 20 include wafer mounting tables 19c and 20c, respectively, that are configured to temporarily mount thereon wafers W transferred between the loader module 18 and the transfer module 11.

Besides the load lock modules 19 and 20, three FOUP (Free Opening Unified Pod) mounting tables 38 and an orienter 39 are connected to the loader module 18. A FOUP 37 serving as a container storing therein, e.g., 25 sheets of wafers W is mounted on each of the FOUP mounting tables 38, and the orienter 39 is configured to pre-align a position of a wafer W unloaded from the FOUP 37.

The load lock modules 19 and 20 are connected to a sidewall of the loader module 18 in a lengthwise direction so as to face the three FOUP mounting tables 38 across the loader module 18 located therebetween. The orienter 39 is provided at one end portion of the loader module 18 in a lengthwise direction.

The loader module 18 includes a scalar dual-arm type transfer arm 40 serving to transfer a wafer W; and three loading ports 41 serving as input ports for wafers W at a sidewall of the loader module 18 and corresponding to the respective FOUP mounting tables 38. The transfer arm 40 takes out a wafer W from the FOUP 37 mounted on the FOUP mounting table 38 via the loading port 41 and loads/unloads the taken-out wafer W into/from the load lock module 19, the load lock module 20 or the orienter 39.

Moreover, the substrate processing system 10 further includes an operation panel 42 provided at one end portion of the loader module 18 in a lengthwise direction. The operation panel 42 has a display including, e.g., a LCD (Liquid Crystal Display), and this display is configured to show a current operational status of each component of the substrate processing system 10.

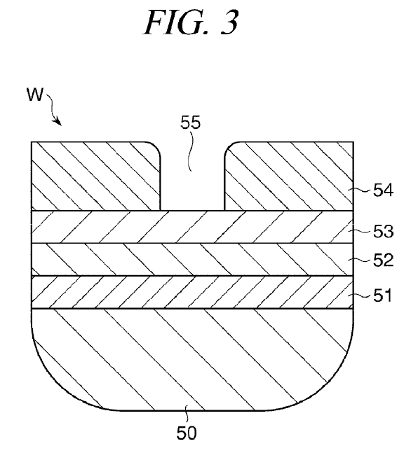

FIG. 3 is a cross sectional view schematically illustrating a structure of a semiconductor wafer on which a plasma process is performed in the substrate processing system of FIG. 1.

As illustrated in FIG. 3, the wafer W has an amorphous carbon film (lower resist film) 51 as a processing target layer, formed on a surface of a silicon base 50; a SiON film (hard mask) 52 formed on the amorphous carbon film 51; an antireflection film (BARC film) 53 formed on the SiON film 52; and a photoresist film (mask layer) 54 formed on the antireflection film 53.

The silicon base 50 is a circular plate-shaped thin plate made of silicon, and the amorphous carbon film 51 is formed on a surface of the silicon base by, e.g., a CVD process. The amorphous carbon film 51 serves as the lower resist film. The SiON film 52 is formed on a surface of the amorphous carbon film 51 by performing a CVD process or a PVD process on the amorphous carbon film 51, and the antireflection film 53 is formed on the SiON film 52 by, e.g., a coating process. The antireflection film 53 is made of a polymer resin containing a dye that absorbs light of a certain wavelength, e.g., an ArF excimer laser beam irradiated toward the photoresist film 54. The antireflection film 53 thus prevents the ArF excimer laser beam transmitted through the photoresist film 54 from reaching the photoresist film 54 again by being reflected by the SiON film 52. The photoresist film 54 is formed on the antireflection film 53 by, e.g., a spin coater (not shown). The photoresist film 54 is made of a positive photosensitive resin. When the photoresist film 54 is exposed to the ArF excimer laser beam irradiated thereto, it becomes soluble in alkali.

On the wafer W configured as described above, an ArF excimer laser beam corresponding to a pattern to be reversed into a preset pattern is irradiated to the photoresist film 54 by a stepper (not shown), and, thus, the photoresist film 54's portion exposed to the ArF excimer laser beam becomes soluble in alkali. Then, a strong alkaline developing solution is dripped onto the photoresist film 54, and, thus, the alkali-soluble portion of the photoresist film 54 gets removed. Accordingly, since the photoresist film 54's portion corresponding to the pattern to be reversed into the preset pattern is removed, the photoresist film 54 provided with the preset pattern, e.g., having an opening 55 at a position where a via hole is to be formed, is only left on the wafer W.

Meanwhile, to meet a demand for miniaturization of a semiconductor device, an opening (via hole or trench) having a small dimension, specifically, having a CD value of about 25 nm to about 30 nm needs to be formed in an etching target film. A minimum dimension producible by photolithography is, however, about 80 nm. Thus, in the etching process on the wafer W, it has been difficult to form an opening having a CD value capable of satisfying the requirement for the miniaturization of the semiconductor device in the etching target film.

The present inventor has conducted various kinds of experiments to develop a method for forming, on the wafer, an opening having a CD value capable of satisfying the requirement for the miniaturization of the semiconductor device, and found out the following. A deposit is deposited on a bottom portion of an opening as well as on a sidewall thereof when a shrinking process is performed to reduce a CD value of the opening formed on the photoresist film of the wafer W. Further, since a thickness of the deposit on the bottom portion of the opening increases in proportion to a thickness of the deposit on the sidewall, the thickness of the deposit on the bottom portion varies depending on a difference in initial CD values. Furthermore, if thicknesses of deposits on bottom portions of openings are different, the deposits on the bottom portion of the openings cannot be removed in the same manner even if the same etching process is performed, which disturbs a uniform process.

The inventor has repeated many intensive researches based on these findings. There was performed a plasma process by using a deposition gas capable of easily depositing a deposit on a sidewall surface of an opening; an anisotropic etching gas unlikely to diffuse in a lateral surface direction of the opening and thus capable of etching a bottom portion of the opening while suppressing deposition of the deposit on the bottom portion of the opening; and a H₂ gas. As a result, the inventor found out the following: 1) a CD value of the opening of the photoresist film can be reduced by a synergy effect of the deposition gas and the anisotropic etching gas; 2) an opening having a width corresponding to the reduced CD value can be formed in a film on the bottom portion of the opening; 3) non-uniformity of CD values can be resolved due to the H₂ gas's effect of facilitating a loading effect, i.e., a phenomenon that a deposition amount of deposit more increases on the sidewall surface of the opening as the opening has a larger CD value; and 4) CD values can be uniformly reduced while non-uniformity of the CD values is maintained to some extent by using an N₂ gas instead of the H₂ gas. Based on these findings, the present inventor has reached the present disclosure.

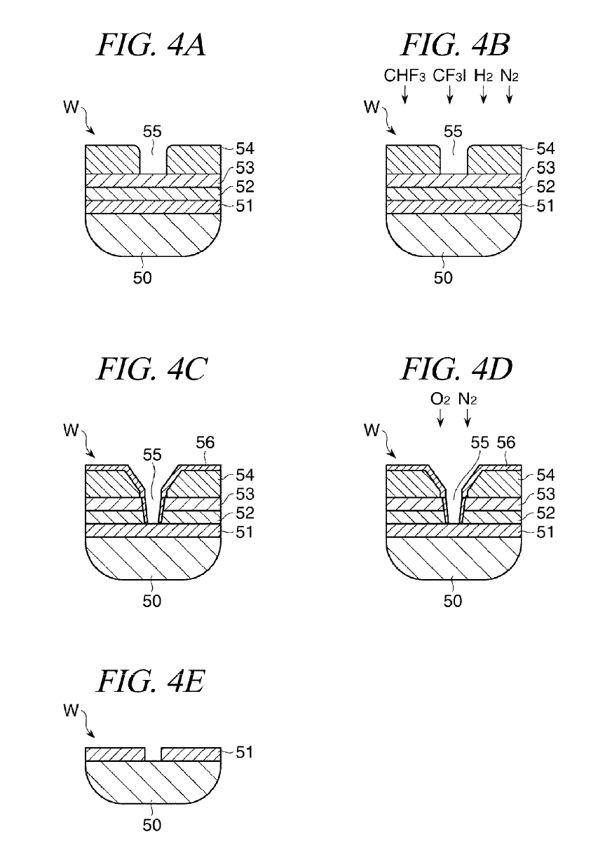

FIGS. 4A to 4E are process diagrams showing the substrate processing method in accordance with the embodiment of the present disclosure.

Referring to FIGS. 4A to 4E, first, a wafer W as shown in FIG. 4A is prepared. The wafer W has an amorphous carbon film 51 as a lower resist film on a silicon base 50; a SiON film 52 as a hard mask; an antireflection film (BARC film) 53; and a photoresist film 54 in sequence. The photoresist film 54 has an opening 55 through which a part of the antireflection film 53 is exposed, and the opening has a width of, e.g., about 75 nm to about 95 nm. The wafer W is loaded into the chamber 22 of the process module 12 (see FIG. 2) and mounted on the mounting table 23.

Then, an internal pressure of the chamber 22 is set to, e.g., about 2×10 Pa (150 mTorr) by the APC valve 26 or the like, and a temperature of the wafer W is set to, e.g., about 60° C. From the lower layer gas feed member 29 of the shower head 24, a CHF₃ gas is fed into the chamber 22 at a flow rate of, e.g., about 200 sccm, and the H₂ gas and the N₂ gas are respectively fed into the chamber 22 at a flow rate of, e.g., about 30 sccm. Further, a CF₃I gas is fed into the chamber 22 at a flow rate of, e.g., about 50 sccm from the upper layer gas feed member 30. Here, a flow rate ratio between the CHF₃ gas and the CF₃I gas is about 4:1. A high frequency power of about 750 W as an excitation power is applied to the mounting table 23, and a high frequency power of about 300 W as a bias power is applied to the mounting table 23. Further, a DC voltage of about −300 V is applied to the shower head 24.

The CHF₃ gas, the H₂ gas, the N₂ gas and the CF₃I gas are excited into plasma by the high frequency power applied to the processing space S, and, thus, ions and/or radicals are generated (see FIG. 4B). The ions and/or radicals generated from the CHF₃ gas collide and react with the surface of the photoresist film 54 or the sidewall surface of the opening 55, so that a deposit is deposited on the reacting portion, thereby reducing a CD value of the opening 55 to some extent. Here, the loading effect is facilitated by radicals generated from the H₂ gas, and, thus, a relatively greater amount of deposit is deposited on a sidewall surface of an opening having a larger CD value, whereas a relatively smaller amount of deposit is deposited on a sidewall surface of an opening having a smaller CD value. As a result, non-uniformity in the CD values can be suppressed. Further, a protective film 56 made of, e.g., carbon nitride is uniformly formed on the sidewall surface and the bottom portion of the opening by radicals generated from the N₂ gas. Accordingly, due to the formation of the protective film 56 by the radicals from the N₂ gas and the deposit deposited by the ions and/or the radicals from the CHF₃ gas and the H₂ gas, the CD value is reduced to, e.g., about 50 nm. Further, the protective film 56 and the deposit on the bottom portion of the opening are removed by anisotropic etching by ions generated from a CF₃I gas, and the BARC film 53 and the SiON film 52 are etched through the photoresist film 54's opening having a width of the reduced CD value.

Accordingly, the CD value is reduced while the non-uniformity in the opening widths is suppressed by depositing the deposit and the protective film 56 on the sidewall surface of the opening 55, and the SiON film 52 on the bottom portion of the opening is etched (non-uniformity-suppressing/opening-width-reducing/shrinking-etching step). Here, a deposition rate of the deposit and the protective film on the sidewall surface of the opening 55 and an etching rate of the SiON film 52 on the bottom portion of the opening are balanced, and the opening 55 becomes to have a cross section of a tapered shape whose opening width is getting reduced toward the bottom of the opening. As a result, an opening of which one end portion in the SiON film 52 has a smaller CD value than the opening width of the opening 55 in the photoresist film 54 is formed (FIG. 4C).

The SiON film 52 is etched until the amorphous carbon film 51 as the lower resist film is exposed, and the opening whose width is reduced to, e.g., about 30 nm is formed in the SiON film 52.

Then, the wafer W having the opening 55 with the reduced width and the etched SiON film 52 is unloaded from the chamber 22 of the process module 12, and then is loaded into the chamber of the process module 13 via the transfer module 11 and mounted on the mounting table therein.

Subsequently, the internal pressure of the chamber 22 is set to, e.g., about 2.6 Pa (20 mTorr) by the APC valve 26 or the like. An O₂ gas is fed from the lower layer gas feed member of the shower head 24 into the chamber at a flow rate of about 180 sccm, and an N₂ gas is also fed from the upper layer gas feed member into the chamber at a flow rate of about 20 sccm. Further, an excitation power of about 1000 W is applied to the mounting table 23, and a bias power is set to 0 W. Here, the O₂ gas and the N₂ gas are excited into plasma by the high frequency power applied to the processing space S, and, thus, ions and/or radicals are generated (FIG. 4D). These ions and/or radicals collide and react with the amorphous carbon film 51's portion which is not covered by the photoresist film 54, the deposit and the protective film 56 on the sidewall surface of the opening 55 and the SiON film, thereby etching the corresponding portion. Here, the amorphous carbon film 51 is etched until the silicon base 50 is exposed, and, as a result, an opening having a width reduced to, e.g., about 30 nm is formed in the amorphous carbon film 51. At this time, the photoresist film 54; the deposit and the protective film 56 on the surface of the photoresist film 54 and/or the sidewall surface of the opening 55; the BARC film 53 and the SiON film 52 are removed at the same time (FIG. 4E).

Thereafter, the wafer W is unloaded from the chamber of the process module 13, and the process is finished.

On the processed wafer W, an etching process is performed by a well-known method, so that a wafer W having an opening of a desired pattern dimension in the silicon base 50 is obtained.

In accordance with the present embodiment, in the non-uniformity-suppressing/opening-width-reducing/shrinking-etching step, the CHF₃ gas capable of easily depositing the deposit on the sidewall surface of the opening 55 is used as the deposition gas; the CF₃I gas capable of easily etching an underlying layer while suppressing deposition of the deposit on the bottom portion of the opening is used as the anisotropic etching gas; the H₂ gas capable of facilitating the loading effect by the deposition of the deposit; and the N₂ gas capable of reducing the opening width by forming the thin protective film of uniform thickness on the inner wall surface of the opening are used. Thus, the CD value of the opening 55 of the photoresist film 54 can be uniformly reduced to a certain width, e.g., about 50 nm while the non-uniformity of opening widths is suppressed, and the SiON film 52 and the amorphous carbon film 51 can be etched based on the reduced CD value.

That is, in accordance with the present embodiment, a non-uniformity-suppressing step of reducing the CD value of the opening 55 while suppressing the non-uniformity of the opening widths; an opening-width-reducing step of reducing the CD value; and an etching step of etching the SiON film 52 based on the reduced CD value can be performed as a one-step approach. Further, the CD value non-uniformity-suppressing effect by the introduction of the H₂ gas and the opening-width-reducing effect by the introduction of the N₂ gas for uniformly reducing the CD value can be controlled independently.

Accordingly, controllability in the substrate processing method may be improved, thus making it possible to meet the requirement for the miniaturization of the semiconductor device in various ways and, further, to improve productivity of wafers W. Moreover, uniformity of opening widths between lots as well as an opening-width non-uniformity-suppressing effect between the lots can also be improved.

In the present embodiment, since the SiON film 52 contains Si components, the SiON film 52 is highly likely to be etched by ions generated from the CF₃I gas. Accordingly, the SiON film 52 is etched faster than the deposition rate of the deposit on the sidewall surface of the opening 55.

Thus, after the completion of the non-uniformity-suppressing/opening-width-reducing/shrinking-etching step, the opening 55 becomes to have a cross section of a tapered shape whose opening width is getting reduced toward the bottom of the opening.

Here, although the reason why the non-uniformity of CD values can be suppressed by the addition of the H₂ gas cannot be clearly explained, it is deemed that a loading effect, i.e., a phenomenon that a relatively greater amount of deposit is deposited on an opening sidewall surface having a larger CD value, while a relatively smaller amount of deposit is deposited on an opening sidewall surface having a smaller CD value, is facilitated by the addition of a H₂ gas which is a component contained in the deposition gas. As a result, the non-uniformity of the CD values can be suppressed.

A feed amount of the H₂ gas that exhibits the CD non-uniformity-suppressing effect may be adjusted depending on the degree of non-uniformity of the opening widths of the wafer W to be processed. For example, if the non-uniformity of the opening widths is about 10 nm, the feed amount of the H₂ gas may be adjusted such that a volume ratio of the feed amount of the H₂ gas to a feed amount of the anisotropic etching gas becomes about 30±5%. If the non-uniformity of the opening widths is about 20 nm, the feed amount of the H₂ gas is adjusted such that a volume ratio of the feed amount of the H₂ gas to the feed amount of the anisotropic etching gas becomes about 60±5%.

Further, the reason why the CD values can be reduced while the non-uniformity of the CD values is maintained by the addition of the N₂ gas is deemed to be as follows. That is, radicals generated from the N₂ gas react with C components of another processing gas such as the deposition gas, and, thus, the thin protective film made of carbon nitride and having the uniform thickness is formed on the sidewall surface and the bottom surface of the opening 55. The formation of such a protective film allows respective opening widths to be uniformly reduced regardless of their initial CD values and aspect ratios, resulting in reduction of the absolute values of the CD values while maintaining the non-uniformity of the CD values.

A feed amount of the N₂ gas that exhibits the CD reducing effect is adjusted depending on a target reduction width that defines how much the CD value of the wafer W shall be reduced as compared to the case of performing etching by using only the deposition gas and the anisotropic etching gas (shrinking-etching step). That is, if the target reduction width is, e.g., about 10 nm, the feed amount of the N₂ gas is adjusted such that a volume ratio of the feed amount of the N₂ gas to a feed amount of the anisotropic etching gas becomes from about 30±5% to about 60±5%. If the target reduction width is about 25 nm, the feed amount of the N₂ gas is adjusted such that a volume ratio of the feed amount of the N₂ gas to the feed amount of the anisotropic etching gas becomes about 120±5%.

In the present embodiment, a relationship between the feed amounts of the H₂ gas and the N₂ gas is not particularly limited.

In the present embodiment, the CHF₃ gas and the CF₃I gas are used as a basic processing gas. If the uniformity of the CD values needs to be suppressed, the H₂ gas is added thereto. Further, if the absolute values of the CD values need to be reduced, the N₂ gas is added thereto. Furthermore, if necessary, the N₂ gas and the H₂ gas are both added thereto. In a non-uniformity-maintaining/shrinking-etching step, by way of adding the N₂ gas to the CHF₃ gas and the CF₃I gas, the CD values are reduced by a certain uniform width while the non-uniformity of the CD values of the wafer W is maintained. Such a non-uniformity-maintaining/shrinking-etching step can be used to allow wiring patterns having different opening widths to co-exist on a single wafer W and further to satisfy the recent demand for the miniaturization of the semiconductor device.

In the present embodiment, the width of the opening formed in the SiON film 52 is determined depending on a ratio of an etching rate of the SiON film 52 on the bottom portion of the opening 55 to a deposition rate of the deposit and the protective film 56 on the sidewall surface of the opening 55. Therefore, desirably, the feed amount of the CHF₃ gas may be set to be larger than the feed amount of the CF₃I gas in order to form an opening having a width of a reduced CD value of the opening 55.

In the present embodiment, although the CHF₃ gas is used as the deposition gas in the non-uniformity-suppressing/opening-width-reducing/shrinking-etching step, any gas expressed by a general formula of CₓH_{y}F_{z} (x, y and Z are integers including 0) can be used as the deposition gas. Besides the CHF₃ gas, a CH₂F₂ gas, a CH₃F gas, C₅F₈ gas, a C₄F₆ gas or the like can be used, for example.

Meanwhile, the CF₃I gas may be appropriately used as the anisotropic etching gas. Since the CF₃I gas has lower toxicity than that of, e.g., a HBr gas, the CF₃I gas is easy to treat. Besides the CF₃I gas, a CF₃BR gas, a CF₃At gas, a HI gas, a HBr gas, or the like may be used as the anisotropic gas. Further, sulfur (S) or other elements having an atomic weight larger than that of S in group 16 on a periodic table may be used as the anisotropic etching gas instead of a halogen element. A gas containing the halogen element or the elements in the group 16 on the periodic table has low volatility and is unlikely to diffuse in a lateral direction of the opening. Accordingly, this gas may generate plasma capable of etching and removing an underlying layer without depositing a deposit on the bottom portion of the opening. Such a gas may be used in combination with the deposition gas. Further, it is deemed that the plasma of the anisotropic etching gas has low volatility, and it reacts with carbon, so that a certain film is formed to thereby protect the sidewall surface of the opening 55. Further, the plasma of the anisotropic etching is deemed to diffuse toward the bottom portion of the opening due to its ionic force, thereby etching the SiON film 52.

In the present embodiment, the bias power is within a range of about 100 W to about 500 W in the non-uniformity-maintaining/opening-width-reducing/shrinking-etching step. If the bias power is below about 100 W, an etching effect on the bottom portion of the opening may be insufficient. If the bias power exceeds about 500 W, however, the photoresist film 54 may be roughened by sputtering.

In the present embodiment, an internal pressure of the chamber during the etching process may be set to be in the range of about 2.6 Pa (about 20 mTorr) to about 2×10 Pa (about 150 mTorr), desirably, in the range of about 1×10 Pa (about 75 mTorr) to about 2×10 Pa (150 mTorr). If the process pressure is excessively low, a substrate surface may be roughened, whereas the substrate surface may be worn out if the process pressure is excessively high.

In the present embodiment, although the temperature of the wafer W during the etching process is not particularly limited, it may range from about 20° C. to about 100° C.

Further, in the present embodiment, although the amorphous carbon film 51 as the lower resist film is used as the processing target layer, the processing target layer is not limited thereto, but it may be, e.g., a SiO₂ film, a TiN film, or the like.

In the present embodiment, the non-uniformity-suppressing/opening-width-reducing/shrinking-etching step and the etching step for etching the amorphous carbon film 51 may be consecutively performed in the same chamber.

### EXPERIMENTAL EXAMPLES

Now, specific experimental examples of the present disclosure will be explained.

### Experimental Example 1

A plasma etching process was performed on a wafer W of FIG. 3 by using the process module 12 of FIG. 2. As for processing conditions, an internal pressure of the chamber was set to about 2×10 Pa (about 150 mTorr); a temperature of the wafer W, about 60° C.; an excitation power to the mounting table 23, about 750 W; a bias power to the mounting table 23, about 300 W; and a DC voltage to the shower head, about −300 V. Further, a CHF₃ gas, a H₂ gas, a N₂ gas and a CF₃I gas are applied as a processing gas at flow rates of about 200 sccm, about 30 sccm, about 30 sccm and about 50 sccm, respectively. CD values of a photoresist film 54 on a wafer W were non-uniform in the range of about 75 nm to about 95 nm before the plasma etching. However, almost uniform openings having CD values ranging from about 31 nm to about 32 nm were formed in a SiON film 52 after the plasma etching.

### Experimental Example 2

The same plasma etching process as conducted in the experimental example 1 was performed under the same conditions as those of the experimental example 1 excepting that a feed amount of a N₂ gas was changed to about 60 sccm. As a result, almost uniform openings having CD values about 18 nm were formed in a SiON film 52.

### Experimental Example 3

The same plasma etching process as conducted in the experimental example 1 was performed under the same conditions as those of the experimental example 1 excepting that a feed amount of a H₂ gas was set to about 0 sccm (i.e., the H₂ gas was not supplied). As a result, an opening-width-reducing effect could be mainly exhibited, so that non-uniform openings having CD values ranging from about 32 nm to about 40 nm were formed in a SiON film 52.

### Experimental Example 4

The same plasma etching process as conducted in the experimental example 1 was performed under the same conditions as those of the experimental example 1 excepting that a feed amount of a N₂ gas was set to about 0 sccm (i.e., the N₂ gas was not supplied). As a result, an opening-width non-uniformity-suppressing effect could be mainly exhibited, so that almost uniform openings having CD values ranging from about 37 nm to about 39 nm were formed in a SiON film 52.

### Comparative Example 1

The same plasma etching process as conducted in the experimental example 1 was performed under the same conditions as those of the experimental example 1 excepting that feed amounts of a N₂ gas and a H₂ gas were set to about 0 sccm (i.e., the N₂ gas and the H₂ gas were not supplied). As a result, the widths of openings of the wafer W were reduced to some extent and non-uniformity was suppressed, and openings having CD values ranging from about 38 nm to about 47 nm were formed. Further, although an absolute CD value was reduced by increasing the feed amount of a CHF₃ gas, exhibition of a CD non-uniformity-suppressing effect and a CD reducing effect could not be independently controlled.

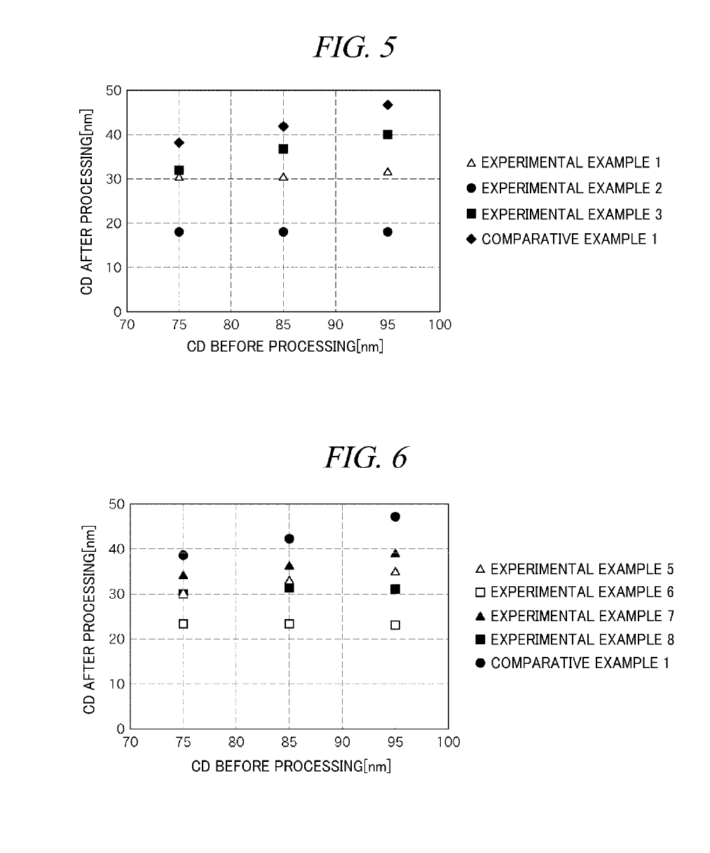

The processing conditions and the results of the experimental examples and comparative example are shown in Table 1. Further, the results are also provided in FIG. 5.

TABLE 1

| | Processing Gas (sccm) | | | | | |
|---|---|---|---|---|---|---|
| | CHF₃ | CF₃I | H₂ | N₂ | CD(Before) | CD(After) |
| Experimental | 200 | 50 | 30 | 30 | 75-95 nm | 31-32 nm |
| Example 1 | | | | | | |
| Experimental | 200 | 50 | 30 | 60 | 75-95 nm | 18 nm |
| Example 2 | | | | | | |
| Experimental | 200 | 50 | — | 30 | 75-95 nm | 32-40 nm |
| Example 3 | | | | | | |
| Experimental | 200 | 50 | 30 | — | 75-95 nm | 37-39 nm |
| Example 4 | | | | | | |
| Comparative | 200 | 50 | — | — | 75-95 nm | 38-47 nm |
| example 1 | | | | | | |

FIG. 5 is a chart that shows the results of the experimental examples and the comparative example.

Referring to FIG. 5, in the experimental example 3 in which the CHF₃ gas, the CF₃I gas and the N₂ gas were used as the processing gas, a straight line connecting respective CD values is shifted downward in parallel as compared to the case of the comparative example 1 in which only the CHF₃ gas and the CF₃I gas were used as the processing gas. This result shows that the CD values were reduced while their non-uniformity was maintained. That is, it is found out that a CD reducing effect can be achieved by adding the N₂ gas to the conditions of the comparative example 1.

Further, in the experimental example 1 in which the H₂ gas and the N₂ gas were used as the processing gas in addition to the CHF₃ gas and the CF₃I gas, a straight line connecting respective CD values is shifted downward as compared to the case of the comparative example 1 and becomes substantially horizontal without inclination. That is, it is found out that a CD non-uniformity-suppressing effect as well as a CD reducing effect can be achieved by adding the H₂ gas and the N₂ gas to the conditions of the comparative example 1.

Moreover, in the experimental example 2 in which the feed amount of the N₂ gas is set to be twice the feed amount of the H₂ gas, a straight line connecting respective CD values is greatly shifted downward by about 12 mm to about 13 mm as compared to the case of the experimental example 1. That is, it is found out that the CD value reducing effect can be improved by increasing the feed amount of the N₂ gas.

Below, other experimental examples of the present disclosure will be described.

In the present disclosure, the H₂ gas functions to facilitate a loading effect by deposition of deposits. Through various experiments, the present inventor has found out that the same result can be achieved even when a deposition gas such as a CHF₃ gas or a CH₂F₂ gas is used instead of the H₂ gas.

### Experimental Example 5

The same plasma etching process as conducted in the experimental example 1 was performed excepting that a CHF₃ gas, which is a deposition gas, was used instead of the H₂ gas in the experimental example 1 and a CHF₃ gas of about 40 sccm was added to the feed amount of the CHF₃ gas in the comparative example 1. Before the etching process, CD values of a photoresist film 54 were non-uniform in the range of about 75 nm to about 95 nm. After the plasma etching, however, openings having almost uniform CD values ranging from about 31 nm to about 32 nm were formed in a SiON film 52.

### Experimental Example 6

The same plasma etching process as conducted in the experimental example 5 was performed excepting that an addition amount of a CHF₃ gas was set to about 60 sccm. As a result, openings having almost uniform CD values of about 23 nm were formed in a SiON film 52.

### Experimental Example 7

The same plasma etching process as conducted in the experimental example 5 was performed excepting that a feed amount of a N₂ gas was set to about 0 sccm (i.e., the N₂ gas was not supplied). As a result, an opening-width non-uniformity-suppressing effect could be mainly exhibited, and, thus, openings having almost uniform CD values of about 34 nm to about 39 nm were formed in a SiON film 52.

### Experimental Example 8

The same plasma etching process as conducted in the experimental example 7 was performed excepting that an addition amount of a CHF₃ gas was set to about 60 sccm. As a result, an opening-width non-uniformity-suppressing effect could be mainly exhibited, and, thus, openings having almost uniform CD values of about 30 nm to about 32 nm were formed in a SiON film 52.

The processing conditions and the results of the experimental examples and the comparative example are shown in Table 2. Further, the results are also provided in FIG. 6.

TABLE 2

| | Processing Gas (sccm) | | | | | |
|---|---|---|---|---|---|---|
| | CHF₃ | CF₃I | CHF₃ | N₂ | CD(Before) | CD(After) |
| Experimental | 200 | 50 | 40 | 30 | 75-95 nm | 30-35 nm |
| Example 5 | | | | | | |
| Experimental | 200 | 50 | 60 | 30 | 75-95 nm | 23 nm |
| Example 6 | | | | | | |
| Experimental | 200 | 50 | 40 | — | 75-95 nm | 34-39 nm |
| Example 7 | | | | | | |
| Experimental | 200 | 50 | 60 | — | 75-95 nm | 30-32 nm |
| Example 8 | | | | | | |
| Comparative | 200 | 50 | — | — | 75-95 nm | 38-47 nm |
| example 1 | | | | | | |

FIG. 6 shows the results of the experimental examples and the comparative example.

Referring to FIG. 6, from the results of the experimental examples 5 and 6, it can be found that, as in the case of using the H₂ gas, a CD non-uniformity-suppressing effect can also be exhibited even when the CHF₃ gas as the deposition gas is used instead of the H₂ gas. Further, the results of the experimental examples 7 and 8 indicate that even when the CHF₃ gas as the deposition gas is used instead of the H₂ gas, the CD non-uniformity-suppressing effect and an opening-width-reducing effect can be independently controlled because there are two parameters, although the independent controllability is slightly lower than that in case of using the H₂ gas.

In the above described embodiments, the substrate on which the plasma process is performed is not limited to the semiconductor wafer for semiconductor device, but various substrates for, e.g., a FPD (Flat Panel Display) including a LCD (Liquid Crystal Display), a photomask, a CD substrate, or a print substrate may be used.

Further, an object of the present disclosure can also be achieved by providing a storage medium storing therein a program code of software implementing the functions of the embodiments to a system or an apparatus, and reading and executing the program code stored in the storage medium by a computer (or a CPU, a MPU or the like) of the system or the apparatus.

In this case, the program code itself read from the storage medium executes the functions of the embodiments described above, and the present disclosure is embodied by the program code and the storage medium storing therein the program code.

Further, as the storage medium for providing the program code, it may be possible to use, e.g., a floppy (registered trademark) disc, a hard disc, a magneto-optical disc, an optical disc such as a CD-ROM, a CD-R, a CD-RW, a DVD-ROM, a DVD-RAM, a DVD-RW, DVD+RW or the like, a magnetic tape, a non-volatile memory card, a ROM or the like. Otherwise, the program code may also be downloaded through a network.

Furthermore, the present disclosure includes a case in which the functions of the embodiments described above may be implemented by executing the program code read by the computer and an OS (Operating System) or the like operated on the computer executes a part or all of actual processes based on instructions of the program code so that the functions of the embodiments described above are implemented by these processes.

Moreover, the present disclosure also includes a case in which the program code read from the storage medium is written in a memory provided in a function extension board inserted into the computer or in a function extension unit connected to the computer, and then a CPU or the like, which has the extension function in the extension board or the extension unit, executes a part or all of actual processes based on instructions of the program code, so that the functions of the embodiments described above is implemented by these processes.

What is claimed is:

1. A substrate processing method for processing a substrate having a processing target layer, an intermediate layer and a mask layer formed on top of each other in sequence, the mask layer having openings through which a part of the intermediate layer is exposed, the method comprising:
a non-uniformity-suppressing/shrinking-etching process of performing a shrinking-etching process and a non-uniformity-suppressing process as a single process,
wherein in the shrinking-etching process, the intermediate layer forming bottom portions of the openings is etched while widths of the openings are reduced by plasma generated from a gaseous mixture of a deposition gas, an anisotropic etching gas and a hydrogen (H₂) gas, and in the non-uniformity-suppressing process, non-uniformity in widths of the openings is suppressed by facilitating deposition of deposits on sidewall surfaces of the openings of the mask layer.

2. The substrate processing method of claim 1, wherein in the non-uniformity-suppressing/shrinking-etching process, a feed amount of the hydrogen (H₂) gas is controlled depending on the non-uniformity in the widths of the openings.

3. The substrate processing method of claim 2, wherein the feed amount of the hydrogen (H₂) gas is controlled such that a volume ratio of the feed amount of the hydrogen (H₂) gas to a feed amount of the anisotropic etching gas is within a range of about 25% to about 65%.

4. The substrate processing method of claim 1, wherein in the non-uniformity-suppressing/shrinking-etching process, a deposition gas is used instead of the hydrogen (H₂) gas.

5. A substrate processing method for processing a substrate having a processing target layer, an intermediate layer and a mask layer formed on top of each other in sequence, the mask layer having openings through which a part of the intermediate layer is exposed, the method comprising:
a non-uniformity-maintaining/shrinking-etching process of performing a shrinking-etching process and an opening-width-reducing process as a single process,
wherein in the shrinking-etching process, the intermediate layer forming bottom portions of the openings is etched while widths of the openings are reduced by plasma generated from a gaseous mixture of a deposition gas, an anisotropic etching gas and a nitrogen (N₂) gas, and
in the opening-width-reducing process, widths of the openings are reduced while non-uniformity in the widths of the openings is maintained by forming a thin film on inner wall surfaces of the openings of the mask layer.

6. The substrate processing method of claim 5, wherein in the non-uniformity-maintaining/shrinking-etching process, a feed amount of the nitrogen (N₂) gas is controlled depending on a reduction width of the opening.

7. The substrate processing method of claim 6, wherein the feed amount of the nitrogen (N₂) gas is controlled such that a volume ratio of the feed amount of the nitrogen (N₂) gas to a feed amount of the anisotropic etching gas is within a range of about 25% to about 125%.

8. A substrate processing method for processing a substrate having a processing target layer, an intermediate layer and a mask layer formed on top of each other in sequence, the mask layer having openings through which a part of the intermediate layer is exposed, the method comprising:
a non-uniformity-suppressing/opening-width-reducing/shrinking-etching process of performing a shrinking-etching process, a non-uniformity-suppressing process and an opening-width-reducing process as a single process,
wherein in the shrinking-etching process, the intermediate layer forming bottom portions of the openings is etched while widths of the openings are reduced by plasma generated from a gaseous mixture of a deposition gas, an anisotropic etching gas, a hydrogen (H₂) gas and a nitrogen (N₂) gas,
in the non-uniformity-suppressing process, non-uniformity in the widths of the openings is suppressed by facilitating deposition of deposits on sidewall surfaces of the openings of the mask layer, and
in the opening-width-reducing process, the widths of the openings are reduced by forming a thin film on inner surfaces of the openings.

9. The substrate processing method of claim 8, wherein in the non-uniformity-suppressing/opening-width-reducing/shrinking-etching process, a feed amount of the hydrogen (H₂) gas is controlled depending on the non-uniformity in the widths of the openings, and a feed amount of the nitrogen (N₂) gas is controlled depending on a reduction width of the opening.

10. The substrate processing method of claim 9, wherein the feed amounts of the hydrogen (H₂) gas and the nitrogen (N₂) gas are controlled such that volume ratios of the feed amounts of the hydrogen (H₂) gas and the nitrogen (N₂) gas to a feed amount of the anisotropic etching gas are within a range of about 25% to about 65% and within a range of about 25% to about 125%, respectively.

11. The substrate processing method of claim 8, wherein in the non-uniformity-suppressing/opening-width-reducing/shrinking-etching process, a deposition gas is used instead of the hydrogen (H₂) gas.

12. The substrate processing method of claim 1, wherein the deposition gas is represented by a general formula of CₓH_{y}F_{z} (x, y and Z are 0 or positive integers).

13. The substrate processing method of claim 5, wherein the deposition gas is represented by a general formula of CₓH_{y}F_{z} (x, y and Z are 0 or positive integers).

14. The substrate processing method of claim 8, wherein the deposition gas is represented by a general formula of CₓH_{y}F_{z} (x, y and Z are 0 or positive integers).

15. The substrate processing method of claim 12, wherein the deposition gas is a CHF₃ gas.

16. The substrate processing method of claim 13, wherein the deposition gas is a CHF₃ gas.

17. The substrate processing method of claim 14, wherein the deposition gas is a CHF₃ gas.

18. The substrate processing method of claim 1, wherein the anisotropic etching gas is a gas containing bromine (Br) or a halogen element having an atomic number greater than that of bromine (Br), or sulfur (S) or other elements having an atomic number greater than that of sulfur (S) in a group 16 on a periodic table.

19. The substrate processing method of claim 5, wherein the anisotropic etching gas is a gas containing bromine (Br) or a halogen element having an atomic number greater than that of bromine (Br), or sulfur (S) or other elements having an atomic number greater than that of sulfur (S) in a group 16 on a periodic table.

20. The substrate processing method of claim 8, wherein the anisotropic etching gas is a gas containing bromine (Br) or a halogen element having an atomic number greater than that of bromine (Br), or sulfur (S) or other elements having an atomic number greater than that of sulfur (S) in a group 16 on a periodic table.

21. The substrate processing method of claim 18, wherein the anisotropic etching gas is a CF₃I gas, a CF Br gas, a HI gas or a HBr gas.

22. The substrate processing method of claim 19, wherein the anisotropic etching gas is a CF₃I gas, a CF₃Br gas, a HI gas or a HBr gas.

23. The substrate processing method of claim 20, wherein the anisotropic etching gas is a CF₃I gas, a CF₃Br gas, a HI gas or a HBr gas.
